(19) United States
(12) Patent Application Publication
(10) Pub. No.: US 2026/0173789 A1
(43) Pub. Date: Jun. 18, 2026

(54) SUBSTRATE PROCESSING APPARATUS AND MEASURING METHOD

(71) Applicant: Tokyo Electron Limited, Tokyo (JP)

(72) Inventors: Shun TSUNOMACHI, Kumamoto (JP); Koki WAKATABI, Kumamoto (JP)

(21) Appl. No.: 19/419,480

(22) Filed: Dec. 15, 2025

(30) Foreign Application Priority Data
Dec. 16, 2024 (JP) 2024-219630

(51) Int. Cl. H10P 72/00; H10P 72/76

(52) U.S. Cl. CPC H10P 72/0414; H10P 72/0616; H10P 72/7618

(57) ABSTRACT

A substrate processing apparatus includes a rotary holding unit, a supply unit including a nozzle, a valve disposed in a supply line, a filter disposed in a portion of the supply line between the valve and the nozzle, a cup, a liquid receiving unit, a drive unit, and a controller. The controller is configured to perform a first process of controlling the supply and the valve to eject a processing liquid from the nozzle into the liquid receiving unit while the nozzle is positioned above the liquid receiving unit, and a second process of controlling the drive unit to move the nozzle to a position above the substrate held by the rotary holding unit and to supply the processing liquid from the nozzle to the substrate while continuously ejecting the processing liquid from the nozzle during the first process.

### CROSS-REFERENCE TO RELATED APPLICATIONS

This application is based on and claims priority from Japanese Patent Application No. 2024-219630, filed on Dec. 16, 2024, with the Japan Patent Office, the disclosure of which is incorporated herein in its entirety by reference.

### TECHNICAL FIELD

The present disclosure relates to a substrate processing apparatus and a substrate processing method.

### BACKGROUND

International Patent Publication No. WO 2021/230103 discloses a substrate liquid processing apparatus configured to suppress the mixing of particles into a processing liquid supplied to a substrate. The apparatus includes: a supply line having no adjustment mechanism that variably restricts a flow path connecting a supply tank and an ejection nozzle; a drainage line connected to a branch portion between the supply tank and the ejection nozzle in the supply line; a liquid flow adjustment mechanism provided in the drainage line and configured to restrict passage of the processing liquid having a pressure lower than a set pressure; and a controller configured to adjust the set pressure.

### SUMMARY

A substrate processing apparatus includes: a rotary holding unit that holds and rotates a substrate; a supply unit including a nozzle that supplies a processing liquid through a supply line onto an upper surface of the substrate held by the rotary holding unit; a valve disposed in the supply line; a filter disposed in the supply line between the valve and the nozzle; a cup arranged to surround the substrate held by the rotary holding unit from the outside and having a cylindrical side wall and an annular ceiling wall extending inward from an upper end of the side wall; a liquid receiving unit provided in the ceiling wall and including an opening opened upward to receive the processing liquid ejected from the nozzle; a drive unit that moves the nozzle between a position above the substrate held by the rotary holding unit and a position above the liquid receiving unit; and a controller. The controller is configured to perform a first process of controlling the supply and the valve in a state where the nozzle is positioned above the liquid receiving unit to eject the processing liquid from the nozzle to the liquid receiving unit, and a second process of controlling the drive unit to move the nozzle to a position above the substrate held by the rotary holding unit while continuously ejecting the processing liquid from the nozzle by the first process, and to supply the processing liquid from the nozzle onto the substrate.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a plan view schematically illustrating an example of a substrate processing system.

FIG. 2 is a view schematically illustrating an example of a liquid processing unit.

FIG. 3 is a view schematically illustrating an example of a processing liquid supply.

FIG. 4 is a block diagram illustrating an example of main components of a substrate processing system.

FIG. 5 is a schematic view illustrating an example of a hardware configuration of a controller.

FIG. 6 is a flowchart illustrating processing of a substrate.

FIG. 7 is a view illustrating processing of a substrate.

FIG. 8 is a view illustrating processing of a substrate.

FIG. 9 is a view illustrating processing of a substrate.

FIGS. 10A to 10C are views illustrating processing of a substrate.

FIGS. 11A to 11C are views illustrating processing of a substrate.

FIGS. 12A to 12C are views illustrating processing of a substrate.

### DETAILED DESCRIPTION

In the following detailed description, reference is made to the accompanying drawings, which form a part hereof. The illustrative embodiments described in the detailed description, drawings, and claims are not meant to be limiting. Other embodiments may be utilized, and other changes may be made without departing from the spirit or scope of the subject matter presented here.

In the following description, identical reference numerals will be used for elements having the same configuration or function, and redundant descriptions will be omitted. Herein, the terms “upper,” “lower,” “right,” and “left” in the drawings are based on the orientation of the reference numerals in the drawings.

### Substrate Processing System

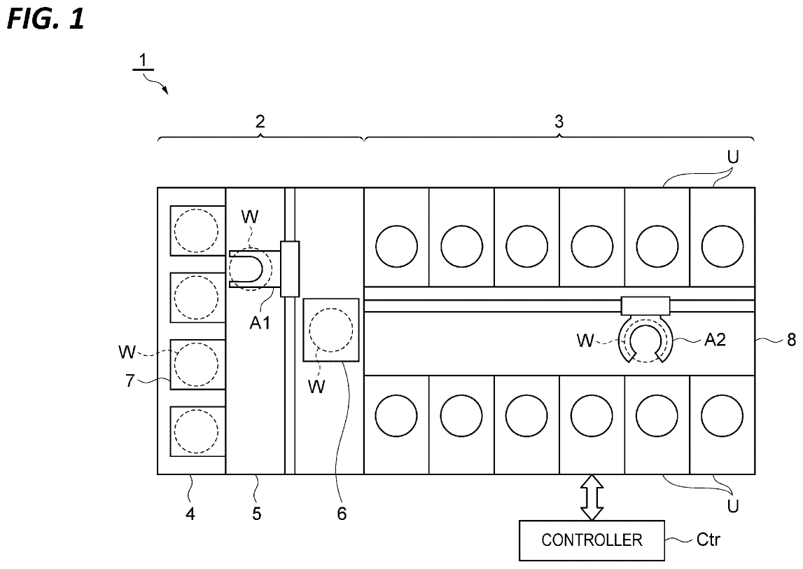

First, referring to FIG. 1, a substrate processing system 1 (a substrate processing apparatus) configured to process a substrate W will be described. The substrate processing system 1 includes a carry-in/out station 2, a processing station 3, and a controller Ctr (a control unit). The carry-in/out station 2 and the processing station 3 may be arranged, for example, in a row in a horizontal direction.

The substrate W may have a disk shape, or may have a plate shape other than circular, such as a polygonal shape. The substrate W may have a cutout portion in which a portion is removed. The cut-out portion may be, for example, a notch (a groove having, e.g., a U-shape or V-shape) or a linear portion (a so-called orientation flat) extending linearly. The substrate W may be, for example, a semiconductor substrate (a silicon wafer), a glass substrate, a mask substrate, a flat panel display (FPD) substrate, or other various types of substrates. The diameter of the substrate W may be, for example, about 200 mm to 450 mm.

The carry-in/out station 2 includes a placement unit 4, a carry-in/out unit 5, and a shelf unit 6. The placement unit 4 includes a plurality of placement stages (not illustrated) arranged in a width direction (the vertical direction in FIG. 1). Each placement stage is configured to allow a carrier 7 to be placed thereon. Each carrier 7 is configured to accommodate at least one substrate W in a sealed state. The carrier 7 includes an opening/closing door (not illustrated) for carry-in/out of a substrate W therethrough.

The carry-in/out unit 5 is disposed adjacent to the placement unit 4 in the direction in which the carry-in/out station 2 and the processing station 3 are arranged (the horizontal direction in FIG. 1). The carry-in/out unit 5 includes an opening/closing door (not illustrated) provided for the placement unit 4. When the carrier 7 is placed on the placement unit 4, both the opening/closing door of the carrier 7 and the opening/closing door of the carry-in/out unit 5 are opened, so that the inside of the carry-in/out unit 5 and the inside of the carrier 7 communicate with each other.

The carry-in/out unit 5 houses a transfer arm A1 and the shelf unit 6. The transfer arm A1 is configured to be horizontally movable in the width direction of the carry-in/out unit 5, to be vertically movable in the vertical direction, and to be pivotable around a vertical axis, based on a signal from the controller Ctr. The transfer arm A1 is configured to take out a substrate W from the carrier 7 and transfer the substrate W to the shelf unit 6, and to receive the substrate W from the shelf unit 6 and return the substrate W into the carrier 7. The shelf unit 6 is located near the processing station 3 and is configured to accommodate a substrate W.

The processing station 3 includes a transfer unit 8 and a plurality of liquid processing units U. The transfer unit 8 extends horizontally, for example, in the direction in which the carry-in/out station 2 and the processing station 3 are arranged (the horizontal direction in FIG. 1). The transfer unit 8 houses a transfer arm A2 (a transfer unit). The transfer arm A2 is configured to be horizontally movable in the longitudinal direction of the transfer unit 8, to be vertically movable in the vertical direction, and to be pivotable around a vertical axis, based on a signal from the controller Ctr. The transfer arm A2 is configured to take out a substrate W from the shelf unit 6 and transfer the substrate W to a liquid processing unit U, and to receive the substrate W from the liquid processing unit U and return the substrate W to the shelf unit 6.

The plurality of liquid processing units U are arranged in a row along the longitudinal direction (the horizontal direction in FIG. 1) on both sides of the transfer unit 8. The configuration of the liquid processing units U will be described later.

The controller Ctr, as will be described in detail later, is configured to control the substrate processing system 1 partially or entirely.

### Liquid Processing Unit

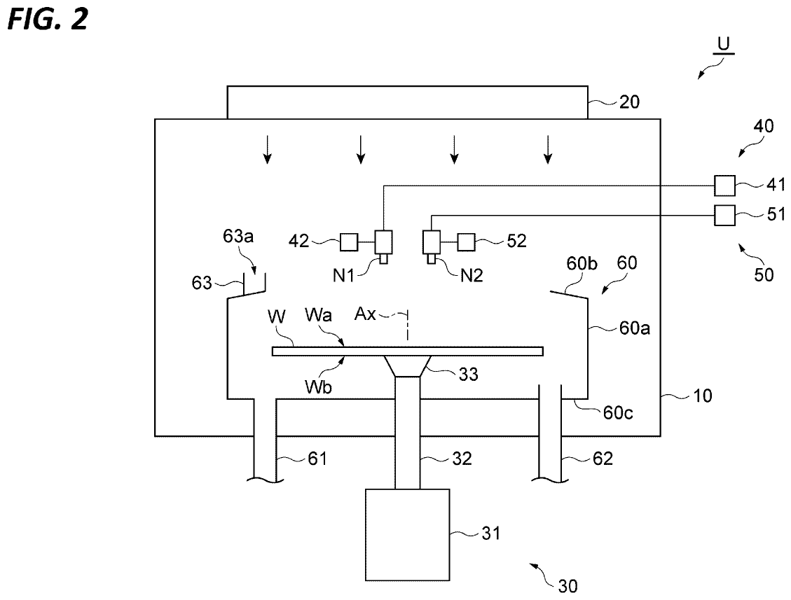

Next, referring to FIG. 2, a liquid processing unit U will be described in detail. The liquid processing unit U is configured to perform a predetermined liquid process (e.g., removal of contamination or foreign substances, or etching) on a substrate W. The liquid processing unit U may be, for example, a single-wafer type cleaning apparatus that cleans substrates W one by one by spin cleaning.

The liquid processing unit U includes a housing 10, an air-blowing unit 20, a rotary holding unit 30, a processing liquid supply 40 (e.g., a liquid supply), a rinse liquid supply 50 (a separate supply), and a cup 60.

The housing 10 accommodates the rotary holding unit 30 inside. The housing 10 is configured to allow carry-in/out of a substrate W. A carry-in/out port (not illustrated) is formed in a side wall of the housing 10. The substrate W is carried into the housing 10 and carried out of the housing 10 through the carry-in/out port by a transfer arm A2.

The air-blowing unit 20 is attached to a ceiling wall of the housing 10. The air-blowing unit 20 is configured, based on a signal from the controller Ctr, to form a downward airflow inside the housing 10. The downward airflow formed by the air-blowing unit 20 flows toward the upper surface Wa of the substrate W held by the rotary holding unit 30.

The rotary holding unit 30 includes a drive unit 31, a shaft 32, and a holding unit 33. The drive unit 31 operates based on a control signal from the controller Ctr and is configured to rotate the shaft 32. The drive unit 31 may be, for example, a power source such as an electric motor.

The holding unit 33 is provided at a terminal end of the shaft 32. The holding unit 33 is configured, for example, to hold a rear surface Wb of the substrate W by suction. That is, the rotary holding unit 30 may be configured to rotate the substrate W about a rotation center axis Ax perpendicular to the upper surface Wa of the substrate W in a substantially horizontal orientation. Alternatively, the holding unit 33 may be configured to hold the substrate W by a plurality of movable members that clamp a peripheral edge of the substrate W instead of suction.

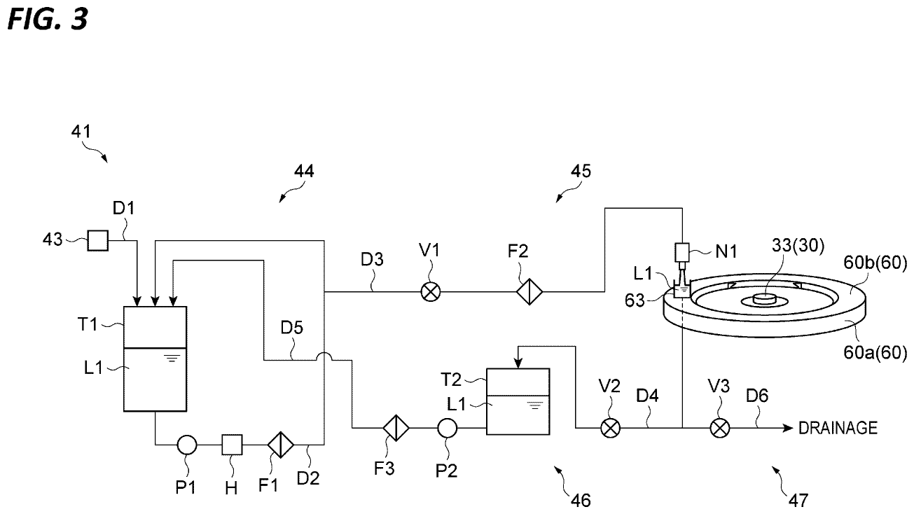

The processing liquid supply 40 includes a processing liquid supply unit 41, a nozzle N1, and a drive unit 42. The processing liquid supply unit 41 functions as a supply source of a processing liquid L1 (see, e.g., FIG. 3). That is, the processing liquid supply unit 41 is configured to deliver the processing liquid L1 to the nozzle N1. The processing liquid L1 delivered by the processing liquid supply unit 41 is supplied from the nozzle N1 onto an upper surface Wa of the substrate W. Details of the processing liquid supply unit 41 will be described later.

The processing liquid L1 may be, for example, an acidic chemical liquid, an alkaline chemical liquid, or an organic chemical liquid. The acidic chemical liquid may include, for example, an SC-2 liquid (a mixed liquid of hydrochloric acid, hydrogen peroxide, and pure water), an SPM liquid (a mixed liquid of sulfuric acid and hydrogen peroxide), an HF liquid (hydrofluoric acid), a DHF liquid (dilute hydrofluoric acid), or an HNO₃+HF liquid (a mixed liquid of nitric acid and hydrofluoric acid). The alkaline chemical liquid may include, for example, an SC-1 liquid (a mixed liquid of ammonia, hydrogen peroxide, and pure water) or hydrogen peroxide. The organic chemical liquid may include, for example, isopropyl alcohol (IPA).

The drive unit 42 operates based on a control signal from the controller Ctr and is configured to move the nozzle N1 horizontally or vertically. The drive unit 42 may be configured, for example, to move the nozzle N1 between a position above the substrate W held by the rotary holding unit 30 and a position above a liquid receiving unit 63 described later.

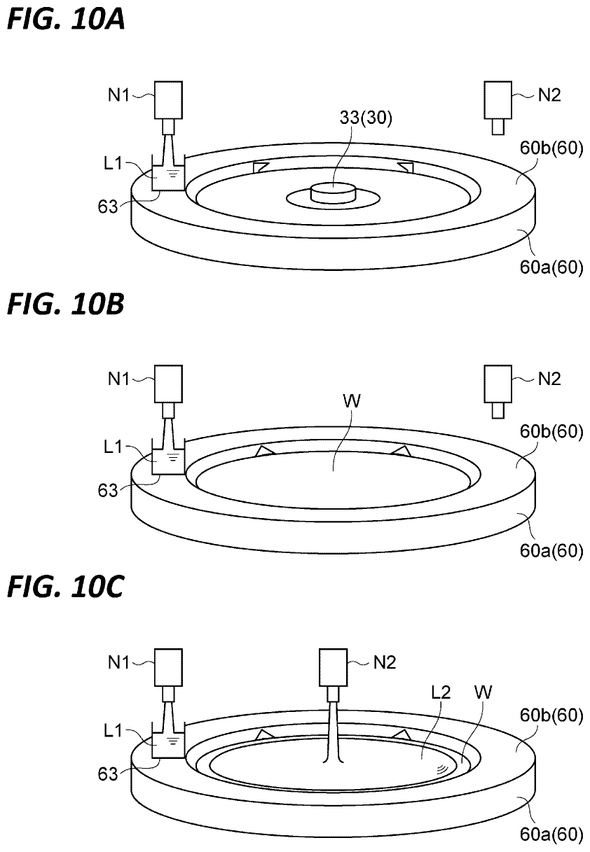

The rinse liquid supply 50 includes a rinse liquid supply unit 51, a nozzle N2 (e.g., a separate nozzle), and a drive unit 52 (e.g., a separate drive unit). The rinse liquid supply unit 51 functions as a supply source of a rinse liquid L2 (see, e.g., FIGS. 10A to 10C). That is, the rinse liquid supply unit 51 is configured to feed the rinse liquid L2 to the nozzle N2. The rinse liquid L2 delivered by the rinse liquid supply unit 51 is supplied from the nozzle N2 onto an upper surface Wa of a substrate W. The rinse liquid L2 may include, for example, pure water (deionized water (DIW)), ozone water, carbonated water (CO₂ water), or ammonia water.

The drive unit 52 operates based on a control signal from the controller Ctr and is configured to move the nozzle N2 horizontally or vertically. The drive unit 52 may be configured, for example, to move the nozzle N2 between a position above the substrate W held by the rotary holding unit 30 and a position outside the substrate W held by the rotary holding unit 30 (e.g., outside the cup 60).

The cup 60 is provided to surround, from the outside, a periphery of the holding unit 33 and a periphery of the substrate W held by the holding unit 33. The cup 60 is configured to collect the processing liquid L1 or the rinse liquid L2 that is splashed from a peripheral edge of the substrate W to the surroundings when the processing liquid L1 or the rinse liquid L2 is supplied onto the upper surface of the substrate W during rotation of the substrate W by the rotary holding unit 30.

The cup 60 includes a side wall 60a, a ceiling wall 60b, and a bottom wall 60c. The side wall 60a has a generally cylindrical shape to surround the holding unit 33 from the outside. The ceiling wall 60b has an annular shape and extends inward from an upper end of the side wall 60a. In the example illustrated in FIG. 2, the ceiling wall 60b extends inward from the upper end of the side wall 60a and is oriented obliquely upward. The bottom wall 60c is provided at a lower end of the side wall 60a to close the lower end.

The bottom wall 60c of the cup 60 is provided with a drain port 61 and an exhaust port 62. The drain port 61 is configured to discharge the processing liquid L1 or the rinse liquid L2 collected by the cup 60 to the outside of the liquid processing unit U. The exhaust port 62 is configured to discharge, to the outside of the liquid processing unit U, a downward airflow formed around the substrate W by the air-blowing unit 20. The downward airflow carries gas generated around the substrate W as the substrate W is processed by the processing liquid L1.

The ceiling wall 60b of the cup 60 is provided with a liquid receiving unit 63. As illustrated in FIG. 2, the liquid receiving unit 63 may be arranged near an inner circumferential edge of the ceiling wall 60b, or in close proximity to the inner circumferential edge of the ceiling wall 60b. The liquid receiving unit 63 includes an opening 63a opened upward to receive the processing liquid L1 ejected from the nozzle N1.

### Processing Liquid Supply Unit

Next, referring to FIG. 3, the processing liquid supply unit 41 will be described in detail. The processing liquid supply unit 41 includes storage tanks T1 and T2, a liquid source 43, a circulation unit 44, a supply 45, a liquid delivery unit 46, and a drainage unit 47. The storage tanks T1 and T2 are configured to temporarily store the processing liquid L1.

The liquid source 43 serves as a supply source of the processing liquid L1. The liquid source 43 is configured to deliver the processing liquid L1 to the storage tank T1 through a pipe D1.

The circulation unit 44 includes a pipe D2, a pump P1, a heater H, and a filter F1 (e.g., a separate filter). Both an upstream end and a downstream end of the pipe D2 are connected to the storage tank T1. That is, the upstream end of the pipe D2 is connected to a lower portion of the storage tank T1. The downstream end of the pipe D2 is connected to an upper portion of the storage tank T1. Accordingly, the pipe D2 constitutes a circulation line through which the processing liquid L1 discharged from the storage tank T1 returns to the storage tank T1.

The pump P1, the heater H, and the filter F1 are provided in the pipe D2 in this order from the upstream side. The pump P1 operates based on a control signal from the controller Ctr and is configured to pump the processing liquid L1 suctioned from the storage tank T1 to the downstream side. The heater H operates based on a control signal from the controller Ctr and is configured to heat the processing liquid L1 flowing through the pipe D2 to a predetermined temperature. The heater H may be, for example, an electric heater. The filter F1 is configured to capture foreign substances (e.g., particles) contained in the processing liquid L1 flowing through the pipe D2.

The supply 45 includes a pipe D3, a valve V1, and a filter F2. The pipe D3 branches off from the downstream side of the filter F1 in the pipe D2. The downstream end of the pipe D3 is connected to the nozzle N1. Accordingly, the pipe D3 constitutes a supply line through which the processing liquid L1 flows to the nozzle N1 via the pipe D2.

A valve V1 and a filter F2 are provided in the pipe D3 in this order from the upstream side. In other words, the filter F2 is disposed in a portion of the pipe D3 between the valve V1 and the nozzle N1. The valve V1 is configured to open and close based on a control signal from the controller Ctr. When the pump P1 operates while the valve V1 is in the open state, the processing liquid L1 in the storage tank T1 flows through the pipes D2 and D3 to the nozzle N1, and the processing liquid L1 is supplied from the nozzle N1 onto the upper surface Wa of a substrate W held by the rotary holding unit 30. The filter F2 is configured to capture foreign substances contained in the processing liquid L1 flowing through the pipe D3.

The liquid delivery unit 46 includes pipes D4 and D5, a valve V2, a pump P2, and a filter F3. The upstream end of the pipe D4 is connected to a lower portion of the liquid receiving unit 63. The downstream end of the pipe D4 is connected to an upper portion of the storage tank T2. The valve V2 is disposed in the pipe D4. The valve V2 is configured to open and close based on a control signal from the controller Ctr. When the valve V2 is in the open state, the processing liquid L1 in the liquid receiving unit 63 flows through the pipe D4 to the storage tank T2.

The upstream end of the pipe D5 is connected to a lower portion of the storage tank T2. The downstream end of the pipe D5 is connected to an upper portion of the storage tank T1. The pump P2 and the filter F3 are provided in the pipe D5 in this order from the upstream side. The pump P2 operates based on a control signal from the controller Ctr and is configured to pump the processing liquid L1 suctioned from the storage tank T2 to the downstream side (the storage tank T1). The filter F3 is configured to capture foreign substances contained in the processing liquid L1 flowing through the pipe D5.

The drainage unit 47 includes a pipe D6 and a valve V3. The pipe D6 branches off from a portion of the pipe D4 between the liquid receiving unit 63 and the valve V2. The downstream end of the pipe D6 extends to the outside of the liquid processing unit U. The valve V3 is provided in the pipe D6. The valve V3 is configured to open and close based on a control signal from the controller Ctr. When the valve V3 is in the open state, the processing liquid L1 in the liquid receiving unit 63 is drained to the outside of the liquid processing unit U through the pipe D6.

### Controller

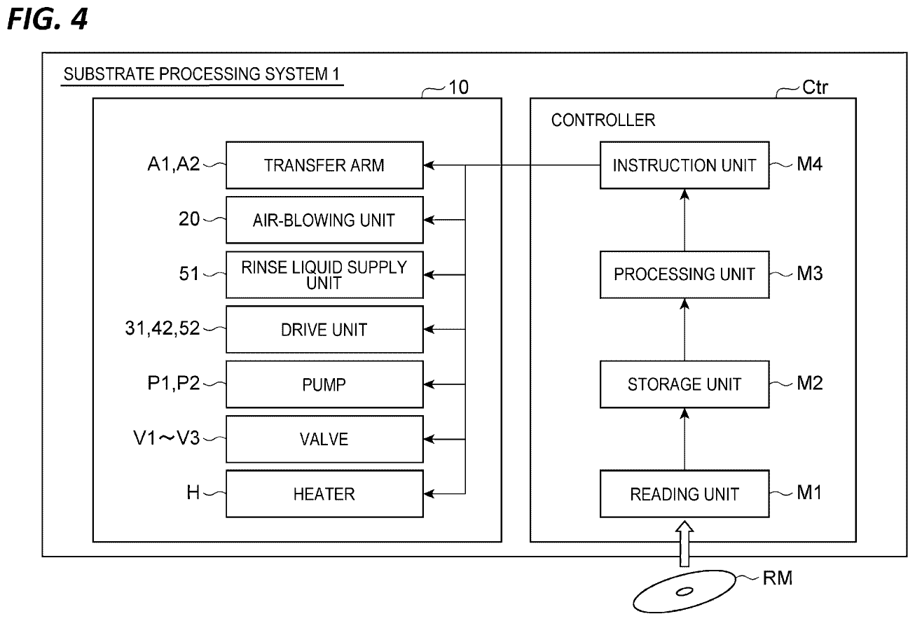

As illustrated in FIG. 4, a controller Ctr includes, as functional modules, a reading unit M1, a storage unit M2, a processing unit M3, and an instruction unit M4. These functional modules merely represent a conceptual division of the functions of the controller Ctr for convenience, and do not necessarily mean that the hardware constituting the controller Ctr is physically separated into such modules. Each functional module may be implemented not only by executing a program, but also by a dedicated electric circuit (e.g., a logic circuit) or an integrated circuit (e.g., ASIC, Application Specific Integrated Circuit) in which such an electric circuit is integrated.

The reading unit M1 is configured to read a program from a computer-readable recording medium RM. The recording medium RM stores a program for operating various components of the substrate processing system 1 (e.g., the transfer arms A1 and A2, the air-blowing unit 20, the rinse liquid supply unit 51, the drive units 31, 42, and 52, pumps P1 and P2, valves V1 to V3, and heater H). The recording medium RM may be, for example, a semiconductor memory, an optical recording disk, a magnetic recording disk, or a magneto-optical recording disk. The recording medium RM may be built into the substrate processing system 1 or may be a separate component from the substrate processing system 1.

The storage unit M2 is configured to store various data. For example, the storage unit M2 may store programs read from the recording medium RM by the reading unit M1, or setting data input by an operator through an external input device (not illustrated).

The processing unit M3 is configured to process various data. For example, the processing unit M3 may be configured to generate operation signals for operating various components of the substrate processing system 1 based on various data stored in the storage unit M2.

The instruction unit M4 is configured to transmit the operation signals generated by the processing unit M3 to various components of the substrate processing system 1.

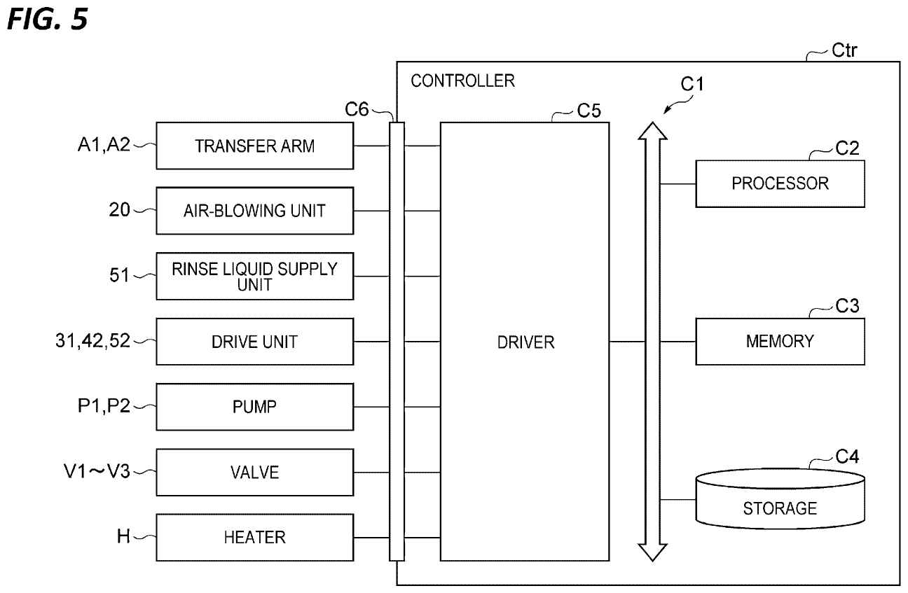

The hardware of the controller Ctr may be configured by one or more control computers. As a hardware configuration, the controller Ctr may include, for example, a circuit C1 as illustrated in FIG. 5. The circuit C1 may be configured with an electric circuit element (e.g., circuitry). The circuit C1 may include, for example, a processor C2, a memory C3 (e.g., storage unit), a storage C4 (e.g., storage unit), a driver C5, and an input/output port C6. The processor C2 executes programs in cooperation with at least one of the memory C3 and the storage C4, and performs input and output of signals through the input/output port C6, thereby constituting the above-described respective functional modules. The memory C3 and the storage C4 function as the storage unit M2. The driver C5 is a circuit configured to drive respective components of the substrate processing system 1. The input/output port C6 performs input and output of signals between the driver C5 and the respective components of the substrate processing system 1.

The substrate processing system 1 may include a single controller Ctr, or may include a controller group (e.g., control unit) including a plurality of controllers Ctr. In the latter case, each of the above-described functional modules may be implemented by a single controller Ctr, or by a combination of two or more controllers Ctr. When the controller Ctr includes a plurality of computers (e.g., circuits C1), each of the functional units may be implemented by a single computer (e.g., circuit C1), or by a combination of two or more computers (e.g., circuits C1). The controller Ctr may include a plurality of processors C2. In this case, each of the functional modules may be implemented by a single processor C2, or by a combination of two or more processors C2.

### Substrate Processing Method

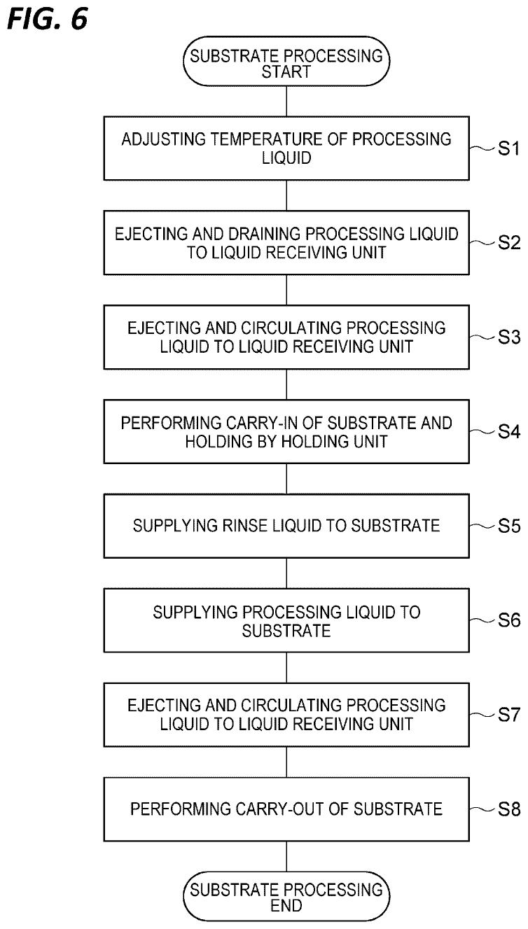

Next, referring to FIGS. 6 to 12, processing of the substrate W will be described. In the following description, a state in which the valves V1 to V3 are closed and the nozzle N1 is positioned above the liquid receiving unit 63 is described as an initial state.

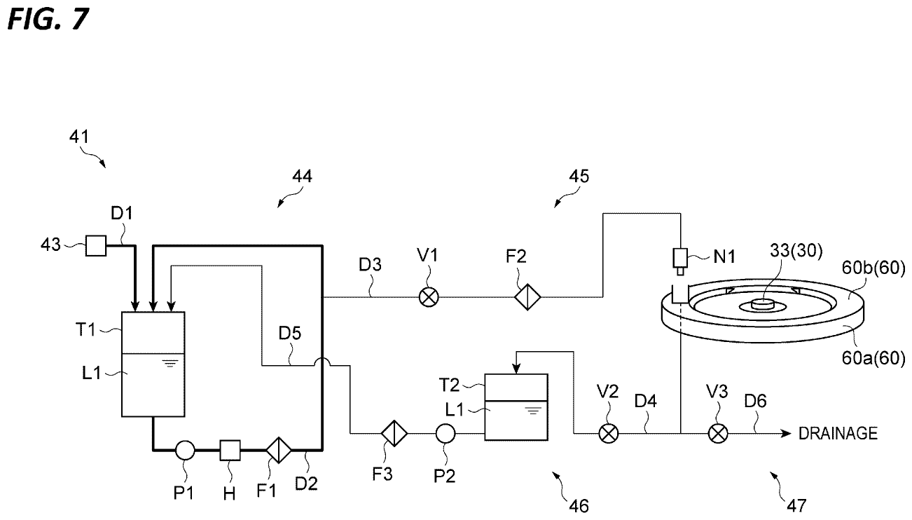

First, as illustrated in FIG. 7, while the processing liquid L1 is supplied from the liquid source 43 to the storage tank T1, the controller Ctr controls the pump P1 and the heater H to heat the processing liquid L1 in the storage tank T1 with the heater H and circulate the processing liquid L1 through the pipe D2 (see, e.g., the bold line in FIG. 7). Accordingly, the processing liquid L1 is purified by the filter F1 and temperature-regulated by the heater H (see, e.g., step S1 in FIG. 6).

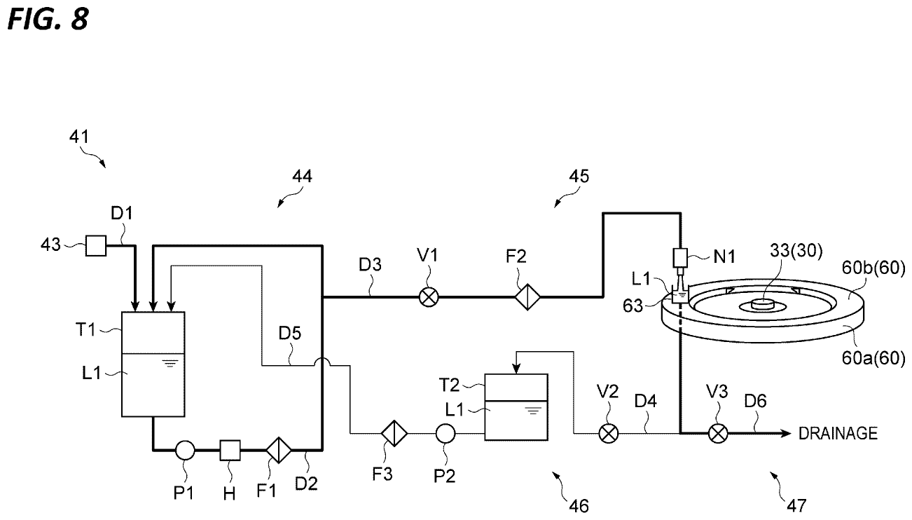

Next, as illustrated in FIG. 8, the controller Ctr controls the valves V1 and V3 to open the valves V1 and V3. As a result, the processing liquid L1 flowing through the pipe D2 is purified by the filter F2 and is ejected from the nozzle N1 through the pipe D3 into the liquid receiving unit 63 (see, e.g., the bold line in FIG. 8 and FIG. 10A). The processing liquid L1 ejected into the liquid receiving unit 63 is drained through the pipes D4 and D6 (see, e.g., step S2 in FIG. 6).

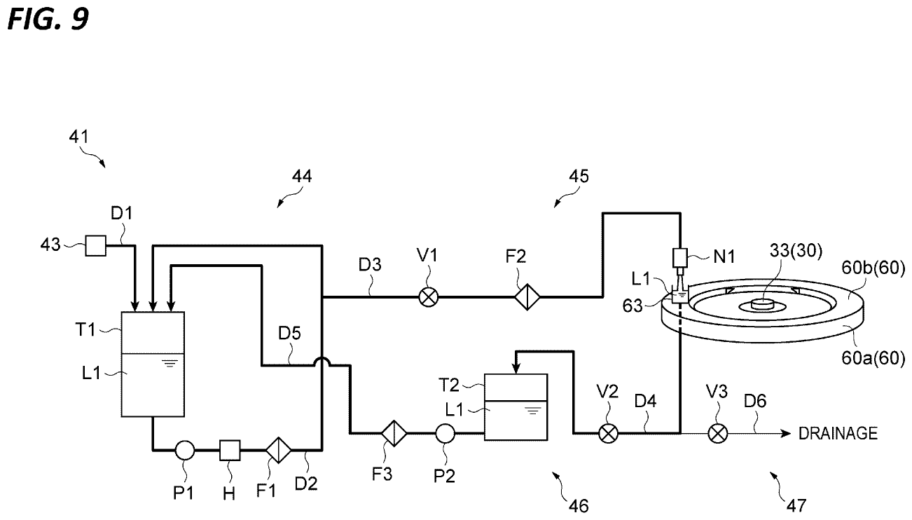

Next, as illustrated in FIG. 9, the controller Ctr controls the valves V2 and V3 to close the valve V3 while opening the valve V2. As a result, the processing liquid L1 ejected into the liquid receiving unit 63 is supplied to the storage tank T2 through the pipe D4. The controller Ctr also controls the pump P2 to deliver the processing liquid L1 in the storage tank T2 to the downstream side through the pipe D5 (see, e.g., the bold line in FIG. 9). Accordingly, the processing liquid L1 is purified by the filter F2 and returned to the storage tank T1. That is, the processing liquid L1 ejected into the liquid receiving unit 63 circulates through the pipe D4, the storage tank T2, the pipe D5, the storage tank T1, the pipe D2, and the pipe D3 (see, e.g., step S3 in FIG. 6).

Next, the controller Ctr instructs the transfer arm A1 to unload one substrate W from a carrier 7 and transfer the substrate W toward one of the liquid processing units U. Then, the controller Ctr instructs the transfer arm A2 to load the substrate W into the housing 10 and cause the holding unit 33 to hold the substrate W (see, e.g., steps S4 in FIG. 6 and FIG. 10B). Next, the controller Ctr instructs the drive unit 31 to rotate the substrate W held by the holding unit 33 at a predetermined rotational speed. It should be noted that, while the substrate W is being carried into the housing 10, ejection of the processing liquid L1 from the nozzle N1 to the liquid receiving unit 63 is continued.

Next, the controller Ctr instructs the drive unit 52 to move the nozzle N2 to a position above the substrate W held by the rotary holding unit 30. The drive unit 52 may move the nozzle N2 so that the nozzle N2 is positioned above a region including the central portion of the substrate W. Subsequently, the controller Ctr instructs the rinse liquid supply unit 51 to supply a rinse liquid L2 from the nozzle N2 onto the upper surface Wa of the substrate W held by the rotary holding unit 30 (see, e.g., step S5 in FIG. 6). As a result, the rinse liquid L2 spreads toward the outer peripheral edge of the substrate W by centrifugal force generated by the rotation of the substrate W, and the entire upper surface Wa of the substrate W is covered with the rinse liquid L2 (see, e.g., FIG. 10C).

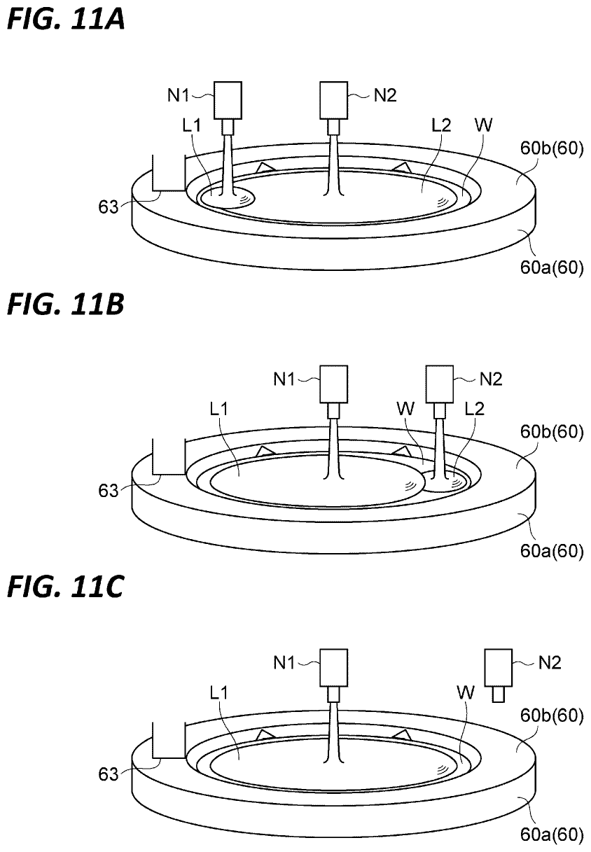

Next, the controller Ctr instructs the drive unit 42 to move the nozzle N1 to a position above the substrate W held by the rotary holding unit 30. At this time, rotation of the substrate W, ejection of the processing liquid L1 from the nozzle N1, and ejection of the rinse liquid L2 from the nozzle N2 are continued. Accordingly, the processing liquid L1 ejected from the nozzle N1 is first supplied to the vicinity of the outer peripheral edge of the substrate W and mixes with the rinse liquid L2 already covering the upper surface Wa of the substrate W (see, e.g., step S6 in FIG. 6 and FIG. 11A).

Subsequently, the drive unit 42 moves the nozzle N1 to be positioned above a region including the central portion of the substrate W. At the same time, the controller Ctr instructs the drive unit 52 to move the nozzle N2 outward from the substrate W. As a result, the liquid covering the upper surface Wa of the substrate W is gradually replaced from the rinse liquid L2 to the processing liquid L1 (see, e.g., FIG. 11B).

Thereafter, the controller Ctr instructs the drive unit 52 to move the nozzle N2 to be positioned outside the substrate W. The controller Ctr also instructs the rinse liquid supply unit 51 to stop supplying the rinse liquid L2 from the nozzle N2. Accordingly, the entire upper surface Wa of the substrate W is covered with the processing liquid L1 (see, e.g., FIG. 11C). As a result, drying of the upper surface Wa of the substrate W is performed by the processing liquid L1.

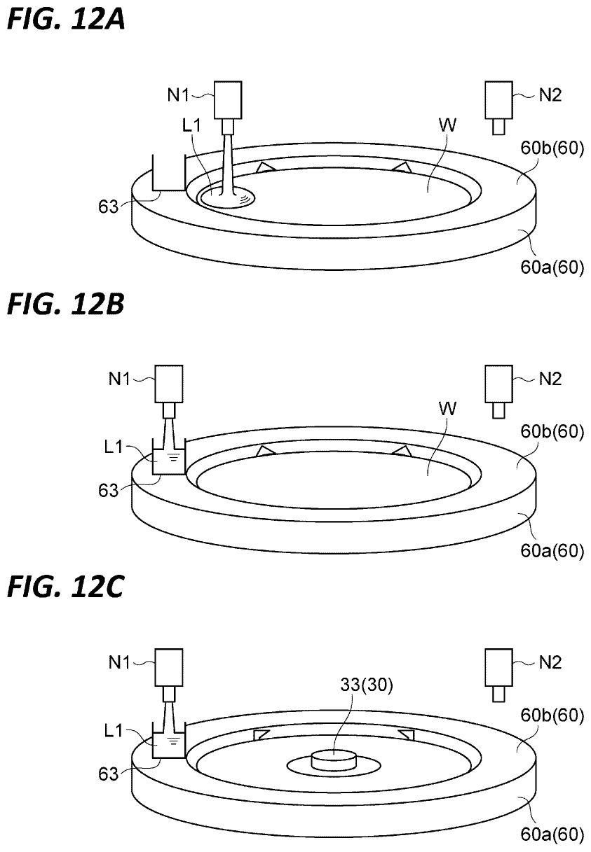

Next, the controller Ctr instructs the drive unit 42 to move the nozzle N1 outward from the substrate W (see, e.g., FIG. 12A). Thereafter, the drive unit 42 moves the nozzle N1 to be positioned above the liquid receiving unit 63 (see, e.g., FIG. 12B). Accordingly, the processing liquid L1 is ejected from the nozzle N1 into the liquid receiving unit 63 (see, e.g., step S7 in FIG. 6). The processing liquid L1 ejected into the liquid receiving unit 63 again circulates through the pipe D4, the storage tank T2, the pipe D5, the storage tank T1, the pipe D2, and the pipe D3 (see, e.g., step S7 in FIG. 6).

Next, the controller Ctr instructs the drive unit 31 to stop rotation of the substrate W held by the holding unit 33. The controller Ctr then instructs the transfer arm A2 to grip the substrate W held by the rotary holding unit 30 and unload it from the housing 10 (see, e.g., FIG. 12C). Next, the controller Ctr instructs the transfer arm A1 to transfer the substrate W to the carrier 7. Thus, processing of one substrate W is completed. While the substrate W is being carried out of the housing 10, ejection of the processing liquid L1 from the nozzle N1 to the liquid receiving unit 63 is continued. Accordingly, during processing of a subsequent substrate W, steps S4 to S8 in FIG. 6 are repeated.

### Action

According to the foregoing examples, the filter F2 is disposed in the pipe D3 so as to be positioned on the downstream side of the valve V1. Therefore, even if foreign substances are mixed into the processing liquid L1 due to dust generation accompanying the opening and closing of the valve V1, the foreign substances are removed by the filter F2 on the downstream side of the valve V1. Accordingly, it becomes possible to suppress adhesion of foreign substances to the substrate W. In addition, according to the foregoing examples, while ejection of the processing liquid L1 from the nozzle N1 toward the liquid receiving unit 63 positioned near the substrate W held by the rotary holding unit 30 is continued, the nozzle N1 is moved to a position above the substrate W, and the processing liquid L1 is supplied from the nozzle N1 to the substrate W. Therefore, the valve V1 is not opened or closed when the processing liquid L1 is supplied to the substrate W. Accordingly, since the processing liquid L1 does not remain in the filter F2 when the valve V1 is closed, the properties of the processing liquid L1 (e.g., temperature) are less likely to change. Thus, before the processing liquid L1 is supplied to the substrate W, there is no need to perform dummy ejection of the processing liquid L1 until the processing liquid L1 reaches properties suitable for processing the substrate W. As a result, it becomes possible to suppress consumption of the processing liquid L1 due to dummy ejection while suppressing adhesion of foreign substances to the substrate W.

According to the foregoing examples, while ejection of the processing liquid L1 from the nozzle N1 is continued, the nozzle N1 is moved to a position above a region including the central portion of the substrate W held by the rotary holding unit 30. Therefore, the processing liquid L1 is likely to spread from the center of the substrate W to the entire substrate W. Accordingly, it becomes possible to process the substrate W more efficiently.

According to the foregoing examples, while ejection of the processing liquid L1 from the nozzle N1 is continued, the nozzle N1 positioned above the substrate W held by the rotary holding unit 30 is moved to an upper side of the liquid receiving unit 63, and the processing liquid L1 is supplied from the nozzle N1 to the liquid receiving unit 63. Therefore, the nozzle N1 moves from above the substrate W to a position above the liquid receiving unit 63 without the valve V1 being closed. Accordingly, at the time of completion of processing of the substrate W, the processing liquid L1 does not remain in the filter F2. As a result, even when a subsequent substrate W is processed, dummy ejection of the processing liquid L1 is unnecessary, and thus consumption of the processing liquid L1 due to dummy ejection may be further reduced.

According to the foregoing examples, while ejection of the processing liquid L1 from the nozzle N1 is continued, the substrate W is loaded into or unloaded from the housing 10. Therefore, even when the substrates W are sequentially processed, it becomes possible to suppress consumption of the processing liquid L1 due to dummy ejection while suppressing adhesion of foreign substances to the substrate W.

According to the foregoing examples, the rinse liquid L2 is supplied to the substrate W before the processing liquid L1 is supplied to the substrate W. Accordingly, after the rinse liquid L2 on the upper surface Wa of the substrate W is replaced with the processing liquid L1, drying of the substrate W is performed. Therefore, it becomes possible to suppress adhesion of particles to the substrate W due to generation of watermarks.

According to the foregoing examples, while ejection of the processing liquid L1 from the nozzle N1 and ejection of the rinse liquid L2 from the nozzle N2 are both continued, the nozzle N1 is moved to a position above the substrate W held by the rotary holding unit 30 to supply the processing liquid L1 to the substrate W, and at the same time, the nozzle N2 positioned above the substrate W held by the rotary holding unit 30 is moved outward from the substrate W. Accordingly, the upper surface Wa of the substrate W is always covered with either the rinse liquid L2 or the processing liquid L1. Therefore, generation of watermarks may be further suppressed.

According to the above example, while the processing liquid L1 circulates through the pipe D2, foreign substances contained in the processing liquid L1 are removed by the filter F1. Therefore, the purified processing liquid L1 is ejected from the nozzle N1 through the pipe D3. Accordingly, adhesion of foreign substances to the substrate W may be further suppressed.

According to the foregoing examples, the processing liquid L1 ejected into the liquid receiving unit 63 is returned to the storage tank T1, and thereafter ejected again from the nozzle N1 through the pipes D2 and D3. Accordingly, effective utilization of the processing liquid L1 is achieved, thereby further reducing consumption of the processing liquid L1.

### Modification

The disclosure of the present specification is to be regarded as illustrative in all respects and not restrictive. Various omissions, substitutions, and modifications may be made to the foregoing examples without departing from the scope and spirit of the claims.
(1) While ejection of the processing liquid L1 from the nozzle N1 is continued, the nozzle N1 may be moved to a position above the substrate W that is held stationary by the rotary holding unit 30 with its rotation stopped. In this case, a liquid pool of the processing liquid L1 is formed on the upper surface Wa of the substrate W that is held stationary. Accordingly, it becomes possible to process the substrate W with a relatively small amount of the processing liquid L1.
(2) The processing liquid supply unit 41 may not include the storage tank T2, and the pipes D4 and D5 may be directly connected to each other. In this case, the processing liquid L1 ejected from the nozzle N1 into the liquid receiving unit 63 is directly returned to the storage tank T1.
(3) The filter F3 may be disposed at any position of the pipes D4 and D5.
(4) The liquid receiving unit 63 may be provided at any position of the ceiling wall 60b.

### Other Examples

Example 1. A a substrate processing apparatus includes: a rotary holding unit that holds and rotates a substrate; a supply unit including a nozzle that supplies a processing liquid onto an upper surface of the substrate held by the rotary holding unit through a supply line; a valve disposed in the supply line; a filter disposed in the supply line between the valve and the nozzle; a cup including a side wall disposed to surround a periphery of the substrate held by the rotary holding unit from an outside and having a cylindrical shape, and an annular ceiling wall extending inward from an upper end of the side wall; a liquid receiving unit provided in the ceiling wall and including an upwardly opened opening that receives the processing liquid ejected from the nozzle; a drive unit that moves the nozzle between a position above the substrate held by the rotary holding unit and a position above the liquid receiving unit; and a controller. The controller is configured to perform a first process of controlling the supply and the valve to eject the processing liquid from the nozzle into the liquid receiving unit while the nozzle is positioned above the liquid receiving unit, and a second process of controlling the drive unit to move the nozzle to a position above the substrate held by the rotary holding unit and to supply the processing liquid from the nozzle to the substrate while continuously ejecting the processing liquid from the nozzle during the first process.

In Example 1, the filter is disposed in the supply line to be positioned on the downstream side of the valve. Therefore, even if foreign substances (e.g., particles) are mixed into the processing liquid due to dust generation accompanying the opening and closing of the valve, the foreign substances are removed by the filter on the downstream side of the valve. Accordingly, it becomes possible to suppress adhesion of foreign substances to the substrate. In addition, in Example 1, while ejection of the processing liquid from the nozzle toward the liquid receiving unit positioned near the substrate held by the rotary holding unit is continued, the nozzle is moved to a position above the substrate, and the processing liquid is supplied from the nozzle to the substrate. Therefore, the valve is not opened or closed when the processing liquid is supplied to the substrate. Accordingly, since the processing liquid does not remain in the filter when the valve is closed, properties of the processing liquid (e.g., temperature) are less likely to change. Thus, before the processing liquid is supplied to the substrate, there is no need to perform dummy ejection of the processing liquid until the processing liquid reaches properties suitable for processing the substrate. As a result, according to Example 1, it becomes possible to suppress consumption of the processing liquid due to dummy ejection while suppressing adhesion of foreign substances to the substrate.

Example 2. In the apparatus of Example 1, the second process may include moving the nozzle to a position above a region including the central portion of the substrate held by the rotary holding unit while continuously ejecting the processing liquid from the nozzle during the first process. In this case, the processing liquid is likely to spread from the center of the substrate to the entire substrate. Accordingly, it becomes possible to process the substrate more efficiently.

Example 3. In the apparatus of Example 1 or Example 2, the second process may include moving the nozzle to a position above the substrate held by the rotary holding unit with the rotation stopped while continuously ejecting the processing liquid from the nozzle during the first process. In this case, a liquid pool of the processing liquid is formed on the upper surface of the substrate that is held stationary. Accordingly, it becomes possible to process the substrate with a relatively small amount of the processing liquid.

Example 4. In the apparatus of any one of Examples 1 to 3, the controller may be configured to perform, after the second process, a third process of controlling the drive unit to move the nozzle positioned above the substrate held by the rotary holding unit to a position above the liquid receiving unit while continuously ejecting the processing liquid from the nozzle during the first process, and to supply the processing liquid from the nozzle to the liquid receiving unit. In this case, the nozzle moves from above the substrate to an upper side of the liquid receiving unit without the valve being closed. Accordingly, at the time of completion of processing of the substrate, the processing liquid does not remain in the filter. Therefore, even when a subsequent substrate is processed, dummy ejection of the processing liquid is unnecessary, and thus consumption of the processing liquid due to dummy ejection may be further suppressed.

Example 5. In the apparatus of any one of Examples 1 to 4, the apparatus may further include a housing accommodating the rotary holding unit and a transfer unit configured to carry the substrate into and out of the housing, and the controller may be configured to perform, after the second process, a fourth process of controlling the transfer unit to carry the substrate into or out of the housing while continuously ejecting the processing liquid from the nozzle by the first process. When ejection of the processing liquid is started or stopped when the substrate is carried into or out of the housing, there may be concerns about the effects of dust generation due to valve operation or stagnation of the processing liquid in the filter each time. However, according to Example 5, ejection of the processing liquid from the nozzle is continued even when the substrate is carried into or out of the housing. Accordingly, even when substrates are sequentially processed, it becomes possible to suppress consumption of the processing liquid due to dummy ejection while suppressing adhesion of foreign substances to the substrates.

Example 6. In the apparatus of any one of Examples 1 to 5, the apparatus may further include a separate supply unit including a separate nozzle configured to supply a rinse liquid onto an upper surface of the substrate held by the rotary holding unit, and a separate drive unit configured to move the separate nozzle between a position above the substrate held by the rotary holding unit and a position outside the substrate held by the rotary holding unit. The controller may be configured to perform, before the second process, a fifth process of controlling the separate drive unit to move a separate nozzle to a position above the substrate held by the rotary holding unit and to supply the rinse liquid to the substrate. In this case, the rinse liquid is supplied to the substrate before the processing liquid is supplied to the substrate.

When the substrate is dried after a rinse liquid is supplied to the substrate, if a pattern is formed on the substrate, there is a concern that the pattern may be damaged or collapse due to the surface tension of the rinse liquid. In particular, when the surface of the substrate is hydrophobic, it is especially noticeable that the centrifugal force acting on the liquid becomes greater near the outer peripheral portion of the substrate, making it likely for the liquid film to break. In this case, in a region of the substrate where the liquid film is broken, there is a concern that watermarks may occur and fine particles may adhere. However, according to Example 6, the processing liquid is supplied after the rinse liquid. Therefore, on the upper surface of the substrate, drying of the substrate is performed after the rinse liquid is replaced with the processing liquid. Accordingly, it becomes possible to suppress the adhesion of particles to the substrate due to the occurrence of watermarks.

Example 7. In the apparatus of Example 6, the first process may include, after the fifth process, while continuously ejecting the processing liquid from the nozzle is continued by the first process and while continuously ejecting the rinse liquid from the separate nozzle by the fifth process, moving the separate nozzle, which is positioned above the substrate held by the rotary holding unit, to a position outside the substrate while moving the nozzle to a position above the substrate held by the rotary holding unit and supplying the processing liquid to the substrate. In this case, the upper surface of the substrate is always covered with either the rinse liquid or the processing liquid. Therefore, it becomes possible to further suppress the occurrence of watermarks.

Example 8. In the apparatus of any one of Examples 1 to 7, the processing liquid may be isopropyl alcohol.

Example 9. The apparatus of any one of Examples 1 to 8 may further include a storage tank that stores the processing liquid, and a circulation unit that returns the processing liquid discharged from the storage tank to the storage tank through a circulation line having an upstream and downstream ends that are connected to the storage tank. The circulation unit may include a separate filter disposed in the circulation line, and the supply line may branch from a downstream side of the separate filter in the circulation line and may be connected to the nozzle. In this case, while the processing liquid circulates through the circulation line, foreign substances in the processing liquid are removed by the separate filter. Therefore, purified processing liquid is ejected from the nozzle through the supply line. Accordingly, it becomes possible to further suppress the adhesion of foreign substances to the substrate.

Example 10. The apparatus of Example 9 may further include a liquid delivery unit configured to return the processing liquid ejected to a liquid receiving unit to the storage tank. In this case, the processing liquid ejected to the liquid receiving unit is returned to the storage tank, and then ejected again from the nozzle through the circulation line and the supply line from the storage tank. Therefore, since the effective utilization of the processing liquid is achieved, it becomes possible to further suppress the consumption of the processing liquid.

Example 11. A substrate processing method may include a first step of ejecting a processing liquid from a nozzle to a liquid receiving unit provided on a ceiling wall of a cup arranged to surround a substrate held by a rotary holding unit from the outside, through a supply line in which a valve and a filter are arranged in this order from the upstream side to the downstream side, while the nozzle is positioned above the liquid receiving unit, and a second step of moving the nozzle to a position above the substrate held by the rotary holding unit while continuously ejecting the processing liquid from the nozzle by the first step, and supplying the processing liquid from the nozzle to the substrate. In this case, the same effects as those of the apparatus of Example 1 are obtained.

Example 12. In the method according to Example 11, the second step may include moving the nozzle to a position above a region including a central portion of the substrate held by the rotary holding unit while continuously ejecting the processing liquid from the nozzle by the first step. In this case, the same effects as those of the apparatus according to Example 2 are obtained.

Example 13. In the method of Example 11 or 12, the second step may include moving the nozzle above the substrate that is held by the rotary holding unit with its rotation stopped while continuously ejecting the processing liquid from the nozzle by the first step. In this case, the same effects as those of the apparatus of Example 3 are obtained.

Example 14. The method of any one of Examples 11 to 13 may further include, after the second step, a third step of moving the nozzle positioned above the substrate held by the rotary holding unit to above the liquid receiving unit while continuously ejecting the processing liquid from the nozzle by the first step, and supplying the processing liquid from the nozzle to the liquid receiving unit. In this case, the same effects as those of the apparatus of Example 4 are obtained.

Example 15. The method of any one of Examples 11 to 14 may further include, after the second step, a fourth step of carrying the substrate into or out of a housing accommodating the rotary holding unit while continuously ejecting the processing liquid from the nozzle by the first step. In this case, the same effects as those of the apparatus of Example 5 are obtained.

Example 16. The method of any one of Examples 11 to 15 may further include, before the second step, a fifth step of moving a separate nozzle to a position above the substrate held by the rotary holding unit and supplying a rinse liquid from the separate nozzle to the substrate. In this case, the same effects as those of the apparatus of Example 6 are obtained.

Example 17. In the method of Example 16, the first step may include, after the fifth step, while continuously ejecting the processing liquid from the nozzle by the first step and while continuously ejecting the rinse liquid from the separate nozzle by the fifth step, moving the separate nozzle, which is positioned above the substrate held by the rotary holding unit, to a position outside the substrate while moving the nozzle to a position above the substrate held by the rotary holding unit and supplying the processing liquid to the substrate. In this case, the same effects as those of the apparatus according to Example 7 are obtained.

Example 18. In the method of any one of Examples 11 to 17, the processing liquid may be isopropyl alcohol.

According to the substrate processing apparatus and the substrate processing method of the present disclosure, it becomes possible to suppress adhesion of foreign substances (e.g., particles) to a substrate.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A substrate processing apparatus comprising:
a rotary holder configured to hold and rotate a substrate;
a liquid supply including a nozzle configured to supply a processing liquid onto an upper surface of the substrate held by the rotary holder through a supply line;
a valve disposed in the supply line;
a filter disposed in the supply line between the valve and the nozzle;
a cup including a side wall disposed to surround a periphery of the substrate held by the rotary holder from an outside and having a cylindrical shape, and an annular ceiling wall extending inward from an upper end of the side wall;
a liquid receiver provided in the ceiling wall and including an upwardly opened opening configured to receive the processing liquid ejected from the nozzle;
a driver configured to move the nozzle between a position above the substrate held by the rotary holder and a position above the liquid receiver; and
a controller,
wherein the controller is configured to perform:
a first process of controlling the supply and the valve to eject the processing liquid from the nozzle into the liquid receiver while the nozzle is positioned above the liquid receiver, and
a second process of controlling the driver to move the nozzle to a position above the substrate held by the rotary holder and to supply the processing liquid from the nozzle to the substrate while continuously ejecting the processing liquid from the nozzle during the first process.

2. The substrate processing apparatus according to claim 1, wherein the second process includes moving the nozzle to a position above a region including the central portion of the substrate held by the rotary holder while continuously ejecting the processing liquid from the nozzle during the first process.

3. The substrate processing apparatus according to claim 1, wherein the second process includes moving the nozzle to a position above the substrate held by the rotary holder with the rotation stopped while continuously ejecting the processing liquid from the nozzle during the first process.

4. The substrate processing apparatus according to claim 1, wherein the controller is further configured to perform, after the second process, a third process of controlling the driver to move the nozzle positioned above the substrate held by the rotary holder to a position above the liquid receiver while continuously ejecting the processing liquid from the nozzle during the first process, and to supply the processing liquid from the nozzle to the liquid receiver.

5. The substrate processing apparatus according to claim 1, further comprising:
a housing configured to accommodate the rotary holder; and
a transfer arm configured to carry the substrate into and out of the housing,
wherein the controller is further configured to perform, after the second process, a fourth process of controlling the transfer arm to carry the substrate into or out of the housing while continuously ejecting the processing liquid from the nozzle by the first process.

6. The substrate processing apparatus according to claim 1, further comprising:
a separate supply including a separate nozzle configured to supply a rinse liquid onto an upper surface of the substrate held by the rotary holder; and
a separate driver configured to move the separate nozzle between a position above the substrate held by the rotary holder and a position outside the substrate held by the rotary holder,
wherein the controller is further configured to perform, before the second process, a fifth process of controlling the separate driver to move a separate nozzle to a position above the substrate held by the rotary holder and to supply the rinse liquid to the substrate.

7. The substrate processing apparatus according to claim 6, wherein the first process includes, after the fifth process, while continuously ejecting the processing liquid from the nozzle by the first process, and while continuously ejecting the rinse liquid from the separate nozzle by the fifth process, moving the separate nozzle, which is positioned above the substrate held by the rotary holder, to a position outside the substrate while moving the nozzle to a position above the substrate held by the rotary holder and supplying the processing liquid to the substrate.

8. The substrate processing apparatus according to claim 1, wherein the processing liquid is isopropyl alcohol.

9. The substrate processing apparatus according to claim 1, further comprising:
a storage tank configured to store the processing liquid, and
a circulation path configured to return the processing liquid discharged from the storage tank to the storage tank through a circulation line having upstream and downstream ends that are connected to the storage tank,
wherein the circulation path includes a separate filter disposed in the circulation line, and
the supply line branches from a downstream side of the separate filter in the circulation line and is connected to the nozzle.

10. The substrate processing apparatus according to claim 9, further comprising:
a liquid delivery path configured to return the processing liquid ejected to a liquid receiver to the storage tank.

11. A substrate processing method comprising:
a first process of ejecting a processing liquid from a nozzle to a liquid receiver provided on a ceiling wall of a cup arranged to surround a substrate held by a rotary holder from the outside, through a supply line in which a valve and a filter are arranged in this order from an upstream side to a downstream side, while the nozzle is positioned above the liquid receiver, and
a second process of moving the nozzle to a position above the substrate held by the rotary holder while continuously ejecting the processing liquid from the nozzle by the first process, and supplying the processing liquid from the nozzle to the substrate.

12. The substrate processing method according to claim 11, wherein the second process includes moving the nozzle to a position above a region including a central portion of the substrate held by the rotary holder while continuously ejecting the processing liquid from the nozzle by the first process.

13. The substrate processing method according to claim 11, wherein the second process includes moving the nozzle above the substrate that is held by the rotary holder with its rotation stopped while continuously ejecting the processing liquid from the nozzle by the first process.

14. The substrate processing method according to claim 11, further comprising:
after the second process, a third process of moving the nozzle positioned above the substrate held by the rotary holder to above the liquid receiver while continuously ejecting the processing liquid from the nozzle by the first process, and supplying the processing liquid from the nozzle to the liquid receiver.

15. The substrate processing method according to claim 11, further comprising:
after the second process, a fourth process of carrying the substrate into or out of a housing accommodating the rotary holder while continuously ejecting the processing liquid from the nozzle by the first process.

16. The substrate processing method according to claim 11, further comprising:
before the second process, a fifth process of moving a separate nozzle to a position above the substrate held by the rotary holder, and supplying a rinse liquid from the separate nozzle to the substrate.

17. The substrate processing method according to claim 16, wherein the first process includes, after the fifth process, while continuously ejecting the processing liquid from the nozzle by the first process, and while continuously ejecting the rinse liquid from the separate nozzle by the fifth process, moving the separate nozzle, which is positioned above the substrate held by the rotary holder, to a position outside the substrate while moving the nozzle to a position above the substrate held by the rotary holder and supplying the processing liquid to the substrate.

18. The substrate processing method according to claim 11, wherein
the processing liquid is isopropyl alcohol.
